(19) United States
(12) Patent Application Publication
(10) Pub. No.: US 2025/0120107 A1
(43) Pub. Date: Apr. 10, 2025

(54) SEMICONDUCTOR DEVICE AND MANUFACTURING METHOD

(71) Applicants: Kabushiki Kaisha Toshiba, Tokyo (JP); Toshiba Electronic Devices & Storage Corporation, Tokyo (JP)

(72) Inventors: Yoko IWAKAJI, Meguro (JP); Keiko KAWAMURA, Yokohama (JP); Takako MOTAI, Yokohama (JP)

(73) Assignees: Kabushiki Kaisha Toshiba, Tokyo (JP); Toshiba Electronic Devices & Storage Corporation, Tokyo (JP)

(21) Appl. No.: 18/796,397

(22) Filed: Aug. 7, 2024

(30) Foreign Application Priority Data
Oct. 5, 2023 (JP) 2023-173731

(51) Int. Cl. H01L 29/739; H01L 29/66

(52) U.S. Cl. CPC H10D 12/481; H10D 12/038

(57) ABSTRACT

A semiconductor device according to an embodiment includes a cell region and a termination region adjacent to the cell region. A first insulating film is provided on a first main surface of a semiconductor portion. A first semiconductor region of a first conductivity type provided in the semiconductor portion, a gate electrode, and a gate insulating film covering the gate electrode are provided in the cell region. A second semiconductor region of a second conductivity type provided between the first semiconductor region and the first main surface from the cell region to the termination region is in contact with at least a part of a bottom surface of the gate insulating film. A first member is provided between the second semiconductor region and the first insulating film.

### CROSS-REFERENCE TO RELATED APPLICATION

This application is based upon and claims the benefit of priority from Japanese Patent Application No. 2023-173731, filed Oct. 5, 2023, the entire contents of which are incorporated herein by reference.

### FIELD

Embodiments of the present invention relate generally to a semiconductor device and a manufacturing method.

### BACKGROUND

An insulated gate bipolar transistor (IGBT) is a semiconductor device that can achieve high breakdown voltage and low on-resistance. The IGBT chip has a voltage-resistant structure in a peripheral portion of the chip in order to ensure the breakdown voltage. One example of the voltage-resistant structure is a guard ring structure. The guard ring is usually formed as a p-type diffusion layer on an n-type Si substrate, and is formed by ion implantation and high-temperature annealing treatment. In addition, a structure in which a trench is covered with a deep p-type diffusion layer even at the outermost periphery of the cell region is known.

However, the high-temperature annealing treatment for forming the guard ring may cause defects that degrade element characteristics such as slip of the Si wafer in the process.

Therefore, there is a need for a semiconductor device having improved reliability by suppressing defects in the Si wafer and improved performance by forming a diffusion layer as a voltage-resistant structure.

### DESCRIPTION OF THE DRAWINGS

FIG. 1 is a plan view illustrating a semiconductor device according to a first embodiment.

FIG. 2 is a cross-sectional view taken along the line A-A′ of FIG. 1.

FIG. 3 is an A-A′ cross-sectional view illustrating a semiconductor device according to a first modification of the first embodiment.

FIG. 4 is an A-A′ cross-sectional view illustrating a semiconductor device according to a second modification of the first embodiment.

FIG. 5 is an A-A′ cross-sectional view illustrating a semiconductor device according to a third modification of the first embodiment.

FIG. 6 is a cross-sectional view illustrating a semiconductor device according to a second embodiment.

FIG. 7A is a cross-sectional view illustrating a semiconductor device according to a third embodiment.

FIG. 7B is a cross-sectional view illustrating the semiconductor device according to the third embodiment.

FIG. 7C is a cross-sectional view illustrating the semiconductor device according to the third embodiment.

FIG. 8 is a cross-sectional view illustrating a semiconductor device according to a fourth embodiment.

FIG. 9 is a cross-sectional view illustrating a semiconductor device according to a fifth embodiment.

FIG. 10 is a cross-sectional view illustrating a semiconductor device according to a sixth embodiment.

FIG. 11A is a cross-sectional view illustrating a step of forming a first surface in a method of manufacturing the semiconductor device according to the first embodiment.

FIG. 11B is a cross-sectional view illustrating a step of forming a diffusion layer on the first surface in the method of manufacturing the semiconductor device according to the first embodiment.

FIG. 11C is a cross-sectional view illustrating a step of forming an insulating member on a first main surface and the first surface in the method of manufacturing the semiconductor device according to the first embodiment.

FIG. 11D is a cross-sectional view illustrating a step of digging an excess insulating member in the method of manufacturing the semiconductor device according to the first embodiment.

FIG. 11E is a cross-sectional view illustrating a step of forming a first insulating film after forming a gate electrode and a gate insulating film in a cell region in the method of manufacturing the semiconductor device according to the first embodiment.

FIG. 11F is a cross-sectional view illustrating a step of forming a second electrode, a third electrode, a first conductive region, and the second conductive region in the method of manufacturing the semiconductor device according to the first embodiment.

FIG. 11G is a cross-sectional view illustrating a structure formed on a second main surface in the method of manufacturing the semiconductor device according to the first embodiment.

FIG. 12 is a cross-sectional view illustrating a step of forming a second semiconductor region and a third semiconductor region in a method of manufacturing the semiconductor device according to the third embodiment.

FIG. 13 is a cross-sectional view illustrating a step of forming a second semiconductor region and a third semiconductor region by injecting impurities from a first surface in a method of manufacturing the semiconductor device according to the fourth embodiment.

FIG. 14A is a cross-sectional view illustrating an example of a method of making the depths of a second semiconductor region and a third semiconductor region different in the method of manufacturing the semiconductor device according to the fourth embodiment.

FIG. 14B is a cross-sectional view illustrating an example of a method of making the depths of a second semiconductor region and a third semiconductor region different in the method of manufacturing the semiconductor device according to the fourth embodiment.

FIG. 15A is a cross-sectional view illustrating a step of forming a second bottom surface in a method of manufacturing the semiconductor device according to the fifth embodiment.

FIG. 15B is a cross-sectional view illustrating a step of digging a part of the second bottom surface to form a second bottom surface in the method of manufacturing the semiconductor device according to the fifth embodiment.

FIG. 15C is a cross-sectional view illustrating a step of forming a second semiconductor region and a third semiconductor region in the method of manufacturing the semiconductor device according to the fifth embodiment.

FIG. 16A is a cross-sectional view illustrating a step of forming a second semiconductor region and a third semiconductor region in a method of manufacturing the semiconductor device according to the sixth embodiment.

FIG. 16B is a cross-sectional view illustrating a step of forming a second surface in the method of manufacturing the semiconductor device according to the sixth embodiment.

### DETAILED DESCRIPTION

Hereinafter, embodiments of the present invention will be described with reference to the drawings.

In addition, the drawings are schematic or conceptual, and the relationship between the thickness and the width of each portion, the ratio of the sizes between portions, and the like are not necessarily the same as actual ones. In addition, even in the case of representing the same portion, dimensions or ratios may be illustrated differently from each other depending on the drawings.

In addition, in the present specification and each drawing, the same elements as those described above with respect to the previously described drawings are denoted by the same reference numerals, and detailed description thereof is appropriately omitted.

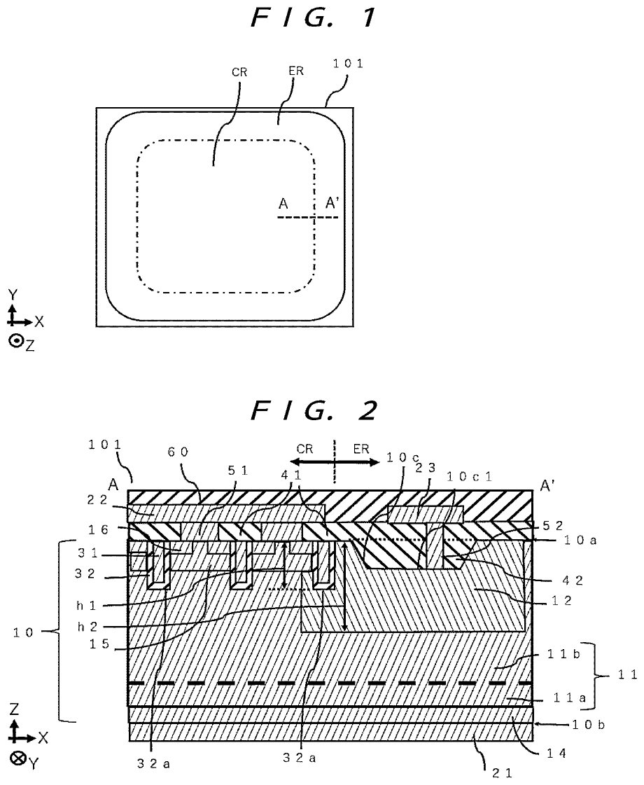

A direction from a first electrode 21 to a second electrode 22 is defined as a Z direction (first direction). A direction perpendicular to the Z direction is defined as an X direction (second direction), and a direction crossing the X direction and the Z direction is defined as a Y direction (third direction). A semiconductor device 101 illustrated in FIG. 2 is a cross-sectional view on the X-Z plane. In addition, the X direction, the Y direction, and the Z direction are illustrated to be in an orthogonal relationship in the present embodiment, but are not limited to being perpendicular and may be in a relationship in which the directions cross each other. For the sake of explanation, a positive direction in the Z direction is referred to as “upper”, and a negative direction in the Z direction is referred to as “lower”. However, the “upper” and “lower” directions are not limited to the gravity direction or directions at the time of mounting the semiconductor device.

In the following description, notations n⁺, n, and n⁻ and p⁺, p, and p⁻ indicate relative levels of impurity concentration in each conductivity type. That is, n⁺ indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺ type and n⁻ type may be simply referred to as n type, p⁺ type, and p⁻ type may be simply referred to as p type.

The depth refers to a length in the Z direction measured from a first main surface 10a. In addition, it does not necessarily refer to the local length at the position illustrated in the drawings, but may refer to the maximum length in the Z direction for the target region.

A semiconductor device according to an embodiment includes a cell region and a termination region adjacent to the cell region. The semiconductor device includes a first insulating film provided on a first main surface of a semiconductor portion and a first electrode provided on a second main surface opposite to the first main surface. In the cell region, a second electrode provided on the first insulating film and electrically connected to the semiconductor portion by a first conductive region, a first semiconductor region of a first conductivity type provided in the semiconductor portion, a gate electrode provided in the semiconductor portion and in contact with the first main surface, and a gate insulating film covering the gate electrode are provided.

A second semiconductor region of a second conductivity type provided between the first semiconductor region and the first main surface from the cell region to the termination region is in contact with at least a part of a bottom surface of the gate insulating film. A first member is provided between the second semiconductor region and the first insulating film.

### First Embodiment

FIG. 1 is a plan view illustrating a semiconductor device according to the present embodiment. FIG. 2 is a cross-sectional view illustrating a cross section taken along the line A-A′ of FIG. 1.

As illustrated in FIGS. 1 and 2, a cell region CR and a termination region ER arranged around the cell region CR and adjacent to the cell region are provided in the semiconductor device 101. In FIG. 1, a region inside the one-dot chain line is the cell region CR, and a region outside the one-dot chain line is the termination region ER. A portion through which a current mainly flows during operation of the semiconductor device 101 is the cell region CR, and a portion arranged around the cell region CR is the termination region ER.

The configuration of the semiconductor device 101 according to the first embodiment will be described with reference to FIG. 2. Hereinafter, a direction from the cell region CR to the termination region ER in FIG. 2 in the X direction is referred to as a termination direction.

The semiconductor device 101 illustrated in FIG. 2 includes a semiconductor portion 10, a first electrode 21, and a first insulating film 41 in the cell region CR and the termination region ER. The semiconductor portion 10 has a first semiconductor region 11 of a first conductivity type. The semiconductor portion 10 is, for example, a semiconductor formed of Si. The first semiconductor region 11 is, for example, an n-type drift layer. The first semiconductor region 11 is formed, for example, by doping Si with phosphorus (P). The first semiconductor region 11 includes a first semiconductor layer 11a and a second semiconductor layer 11b. The first semiconductor layer 11a is provided farther from the first main surface 10a of the semiconductor portion 10 than the second semiconductor layer 11b. For example, the first semiconductor layer 11a is formed of an n⁺-type semiconductor, and the second semiconductor layer 11b is formed of an n-type semiconductor.

The first electrode 21 is provided on a second main surface 10b of the semiconductor portion 10. A first insulating film 41 is provided on the first main surface 10a of the semiconductor portion 10. The semiconductor portion 10, the first electrode 21, and the first insulating film 41 have a structure common to the cell region CR and the termination region ER.

Next, the structure of the termination region ER illustrated in FIG. 2 will be described. The termination region ER includes a second semiconductor region 12 of the second conductivity type and an insulating member 42 (first member 40). That is, FIG. 2 illustrates a case where the first member 40 formed of an insulating material forms the insulating member 42.

The second semiconductor region 12 is formed between the first semiconductor region 11 and the first main surface 10a of the semiconductor portion 10. The second semiconductor region 12 is formed from the cell region CR to the termination region ER. That is, a part of the second semiconductor region 12 is included in the cell region CR. The second semiconductor region 12 is, for example, a p-type diffusion layer, and is formed by injecting, for example, boron (B) into the semiconductor portion 10.

The insulating member 42 is formed at least partially between the second semiconductor region 12 and the first main surface 10a. The second semiconductor region 12, the insulating member 42 (the first member 40), and the second semiconductor region 12 are provided in this order in the termination direction from the cell region to the termination region. The insulating member 42 is in contact with the first insulating film 41. The second semiconductor region 12 and the first insulating film 41 may be partially in contact with each other. The insulating member 42 is, for example, an oxide film containing silicon oxide. In addition, the first insulating film 41 and the insulating member 42 may be formed of the same material or may be formed of different materials.

The first surface 10c refers to a surface including an interface between the insulating member 42 and the second semiconductor region 12. For example, as illustrated in FIG. 2, when the insulating member 42 is in contact with the third semiconductor region 13 and is not in contact with the first semiconductor region 11, the first surface 10c is an interface between the insulating member 42 and the second semiconductor region 12. On the other hand, the insulating member 42 and the first semiconductor region 11 can be partially in contact with each other, and the first surface 10c may include an interface between the insulating member 42 and the second semiconductor region 12. The first surface 10c is closer to the first electrode 21 than the first main surface 10a in the Z-direction.

FIG. 2 illustrates an example in which the insulating member 42 is provided on the first surface 10c and is not provided on the first main surface 10a. However, the shape of the insulating member 42 is not limited to the case of FIG. 2, and the insulating member 42 can also be provided on the first main surface 10a. For example, the insulating member 42 having a uniform thickness can be provided on the first main surface 10a. When the first insulating film 41 and the insulating member 42 are formed of the same material, a portion provided above the first main surface 10a may be defined as the first insulating film 41. Hereinafter, the description will be given with reference to the drawings in which the insulating member 42 is provided on the first surface 10c and is not provided on the first main surface 10a, but the shape of the insulating member 42 is not limited thereto.

Next, the structure of the cell region CR illustrated in FIG. 2 will be described. In the cell region CR, the second electrode 22 is provided on the first insulating film 41. The second electrode 22 is electrically connected to the semiconductor portion 10 through the first conductive region 51. The second electrode 22 and the first conductive region 51 are formed of, for example, a metal containing Al.

The cell region CR includes a gate electrode 31 and a gate insulating film 32. The gate electrode 31 and the gate insulating film 32 are provided in the semiconductor portion 10 and are in contact with the first main surface 10a. The gate insulating film 32 covers the gate electrode 31. The gate electrode 31 and the gate insulating film 32 extend in the Y direction, and a plurality of gate electrodes 31 and a plurality of gate insulating films 32 may be provided in the X direction. All of the plurality of gate electrodes 31 do not need to be electrically connected to each other. The plurality of gate electrodes 31 may include a portion whose potential is controlled (via a gate pad not shown in the figures) and a portion whose potential is not controlled.

Next, an example of a structure formed in the cell region CR in the semiconductor portion 10 will be described. As described below, for example, an IGBT is formed in the cell region CR.

In the cell region CR, the semiconductor portion 10 includes a fourth semiconductor region 14 of the second conductivity type, a fifth semiconductor region 15 of the second conductivity type, and a sixth semiconductor region 16 of the first conductivity type. The fourth semiconductor region 14 is provided between the first electrode 21 and the first semiconductor region 11, and is formed of, for example, a p⁺-type semiconductor. The fourth semiconductor region 14 is, for example, a collector region formed by doping Si with B (boron). The fourth semiconductor region 14 is in ohmic contact with the first electrode 21, for example.

The fifth semiconductor region 15 is provided on the first semiconductor region 11. The fifth semiconductor region 15 is, for example, a p-type diffusion layer. The fifth semiconductor region 15 is formed, for example, by doping Si with B (boron). The fifth semiconductor region 15 is in contact with at least a part of the gate insulating film 32.

The sixth semiconductor region 16 is selectively provided on the fifth semiconductor region 15. The sixth semiconductor region 16 is an emitter region formed of, for example, an n-type semiconductor. The sixth semiconductor region 16 is formed, for example, by doping Si with phosphorus (P). The sixth semiconductor region 16 is in contact with at least parts of the first conductive region 51 and the gate insulating film 32.

In the cell region CR of the semiconductor device 101, for example, an IGBT is formed as described above. The IGBT formed as described above forms an inversion layer in the fifth semiconductor region 15 facing the gate electrode 31 with the gate insulating film 32 interposed therebetween by controlling the potential of the gate electrode 31. When a current flows from the first semiconductor region 11 to the sixth semiconductor region 16 through the inversion layer of the fifth semiconductor region 15, the IGBT is turned on. Up to now, the example of the structure formed in the cell region CR has been described.

Next, the second semiconductor region 12 will be described in more detail. First, an example of a method of forming the second semiconductor region 12 and the insulating member 42 as illustrated in FIG. 2 will be described. A manufacturing method will be described in detail later.

The first surface 10c is formed on the first main surface 10a of the semiconductor portion 10. The first surface 10c is provided by digging the first main surface 10a using, for example, chemical dry etching (CDE). The first surface 10c may be formed by reactive ion etching (RIE) or wet etching.

The first surface 10c may have a bottom portion including a portion perpendicular to the Z direction. For example, as illustrated in FIG. 2, the first surface 10c has a first bottom portion 10c1. The shape of the first surface 10c may be, for example, a bowl-like shape or a shape having a plurality of bottom portions in addition to the shape illustrated in FIG. 2.

The second semiconductor region 12 of the second conductivity type is formed such that at least a part of the second semiconductor region 12 is in contact with the first surface 10c provided in the semiconductor portion 10. The second semiconductor region 12 is, for example, a diffusion layer formed of a p-type semiconductor, and is formed by doping B (boron) and performing annealing treatment. The shape of the second semiconductor region 12 is not limited to the shape illustrated in FIG. 2. For example, the interface between the second semiconductor region 12 and the first semiconductor region 11 is rounded by diffusion of the dopant.

The insulating member 42 is provided so as to be in contact with the second semiconductor region 12 on the first surface 10c. The insulating member 42 is provided at least partially between the first insulating film 41 and the second semiconductor region 12. The insulating member 42 is an oxide film containing silicon oxide such as SiO₂ (silicon dioxide). The insulating member 42 is formed by, for example, CVD. For example, the second semiconductor region 12 and the insulating member 42 are formed by the above steps.

In addition, the termination region ER may have a third electrode 23 provided on the first insulating film 41 and a second conductive region 52 that electrically connects the third electrode 23 and the second semiconductor region 12 to each other.

By providing the third electrode 23 and the second conductive region 52, the electric field dispersed from the cell region CR to the termination region ER by the second semiconductor region 12 can be further dispersed in the direction of the third electrode 23. The third electrode 23 functions as a field plate, and enhances the breakdown voltage by reducing the electric field inside the semiconductor and prevents charge from accumulating in the interlayer insulating film due to the influence of the external environment to improve reliability. The third electrode 23 and the second conductive region 52 are formed of, for example, a metal containing Al.

Next, a positional relationship between the second semiconductor region 12 and the gate insulating film 32 will be described. The second semiconductor region 12 is formed from the cell region CR to the termination region ER, and is in contact with the gate insulating film 32 closest to the termination region ER. In addition, the second semiconductor region 12 is in contact with at least a part of the bottom surface 32a of the gate insulating film 32. That is, the second semiconductor region 12 is in contact with at least a part of the bottom surface 32a of the gate insulating film 32 closest to the termination region ER among the plurality of gate insulating films 32 provided in the cell region CR.

The entire bottom surface 32a may be in contact with the second semiconductor region 12 as illustrated in FIG. 2. When the entire bottom surface 32a is in contact with the second semiconductor region 12, the concentration of the electric field on the bottom surface 32a can be further suppressed, which is desirable.

In addition, the second semiconductor region 12 may extend to the cell region CR beyond the gate insulating film 32 closest to the termination region ER. For example, the second semiconductor region 12 may be in contact with the fifth semiconductor region 15 formed between the gate insulating films 32.

Next, the structures of the second semiconductor region 12 and the gate insulating film 32 will be further described. In the following description, the depth refers to a length in the Z direction measured from the first main surface 10a. In addition, it does not necessarily refer to the local length at the position illustrated in the drawings, but may refer to the maximum length in the Z direction for the target region. For example, when the second semiconductor region 12 has a bowl-like shape, that is, when the length of the second semiconductor region 12 in the Z direction changes in the X direction and the Z-direction length has a maximum value at a predetermined position in the X direction, the depth h2 of the second semiconductor region 12 refers to the maximum length of the second semiconductor region 12 in the Z direction.

The depth h1 of the gate insulating film 32 is a length in the Z direction from the first main surface 10a to the bottom surface 32a. The shape of the bottom surface 32a is not limited to the shape illustrated in FIG. 2, and may be rounded. The depth h2 of the second semiconductor region 12 is formed to be larger than h1, for example. By forming h2 larger than h1, the bottom surface 32a can be completely covered with the second semiconductor region 12. On the other hand, even when h2 is smaller than h1, it is possible to cover, for example, a part of the rounded bottom surface 32a, and a predetermined effect of suppressing the concentration of the electric field on the bottom surface 32a is obtained. From the viewpoint of improving the breakdown voltage, h2 is preferably larger than h1.

Up to now, the semiconductor device 101 according to the first embodiment has been described with reference to FIGS. 1 and 2.

Hereinafter, effects of the semiconductor device 101 according to the present embodiment will be described. In the semiconductor device 101 according to the present embodiment, the first surface 10c is provided in the semiconductor portion 10, and the second semiconductor region 12 is in contact with the bottom surface 32a of the gate insulating film 32 at least partially. The bottom surface 32a and the second semiconductor region 12 are in contact with each other, and the electric field is dispersed to the second semiconductor region 12, thereby suppressing the concentration of the electric field on the bottom surface 32a. The bottom surface 32a is a portion where an electric field tends to concentrate at the time of switching of the semiconductor device formed in the cell region CR, for example, at the time of turn-off of the IGBT. In the semiconductor device 101 according to the present embodiment, the second semiconductor region 12 is provided at least partially between the first semiconductor region 11 and the bottom surface 32a of the gate insulating film 32. As a result, the electric field is dispersed to the second semiconductor region 12, and the concentration of the electric field on the bottom surface 32a of the gate insulating film 32 is suppressed. By suppressing the concentration of the electric field, it is possible to enhance the breakdown voltage.

The second semiconductor region 12 may be in contact with the entire bottom surface 32a. In other words, the bottom surface 32a may be completely covered by the second semiconductor region 12. By completely covering the bottom surface 32a with the second semiconductor region 12, it is possible to further suppress the concentration of the electric field on the bottom surface 32a.

In addition, the second semiconductor region 12 has an effect of promoting discharge of carriers at the time of switching of the semiconductor device 101. For example, when the IGBT is turned off, holes are discharged through the second semiconductor region 12. The structure in which h2 is formed to be greater than h1 and the second semiconductor region 12 is in contact with the fifth semiconductor region 15 can further promote the discharge of holes through the second semiconductor region 12, so that the switching loss of the semiconductor device 101 can be further reduced.

In addition, according to the semiconductor device 101 according to the present embodiment, by providing the first surface 10c, the length of the second semiconductor region 12 measured in the Z direction from the first bottom portion 10cl of the first surface 10c is smaller than the length of the second semiconductor region 12 measured in the Z direction from the first main surface 10a. That is, as compared with the case where the second semiconductor region 12 having the depth h2 is formed without providing the first surface 10c, the required amount of the diffusion length of the dopant is small when the second semiconductor region 12 having the same depth h2 is formed with the first surface 10c provided.

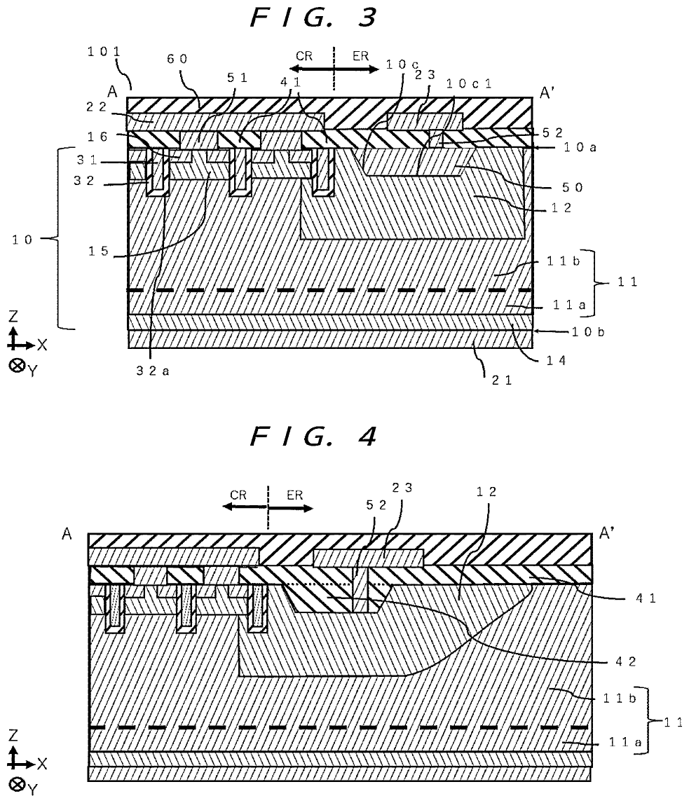

In order to diffuse the dopant deeper, it is necessary to perform annealing treatment at a higher temperature in a longer time, but the high-temperature treatment may cause defects in the Si wafer. In addition, the treatment for a long time inhibits the improvement of the manufacturing efficiency. By providing the first surface 10c, the second semiconductor region 12 having a depth in contact with the bottom surface 32a can be formed even when the diffusion length of the dopant is smaller. That is, since ions implanted into the first semiconductor region 11 from the first surface 10c are diffused in the X direction and the Z direction illustrated in FIG. 3, the second semiconductor region 12 having a depth reaching the bottom surface 32a can be formed.

Due to the diffusion of implanted ions, the deep second semiconductor region 12 can be formed not only immediately below the first surface 10c but also in the vicinity of the first surface 10c by annealing treatment at a low temperature in a short time. That is, it is possible to form a diffusion layer that suppresses the concentration of an electric field on the bottom surface 32a by annealing treatment at a lower temperature with less damage to the Si wafer. In addition, since the annealing treatment can be performed in a shorter time, the manufacturing efficiency can be improved.

As described above, in the semiconductor device 101, the second semiconductor region 12 is in contact with the bottom surface 32a of the gate insulating film 32 at least partially, and the electric field generated on the bottom surface 32a can be dispersed to the second semiconductor region 12 in the termination direction. The concentration of an electric field on the bottom surface 32a at the time of turn-off of the IGBT is suppressed, and a carrier discharge path is formed, so that breakdown resistance of the semiconductor device 101 can be improved.

In addition, by providing the first surface 10c, the amount of heat required to diffuse the dopant for forming the second semiconductor region 12 deep can be reduced. That is, since it is possible to perform the annealing treatment at a lower temperature, it is possible to reduce the risk of generating defects in the Si wafer. In addition, since a diffusion layer having a sufficient depth can be formed by annealing treatment in a shorter time, the manufacturing efficiency can be improved.

### First Modification of First Embodiment

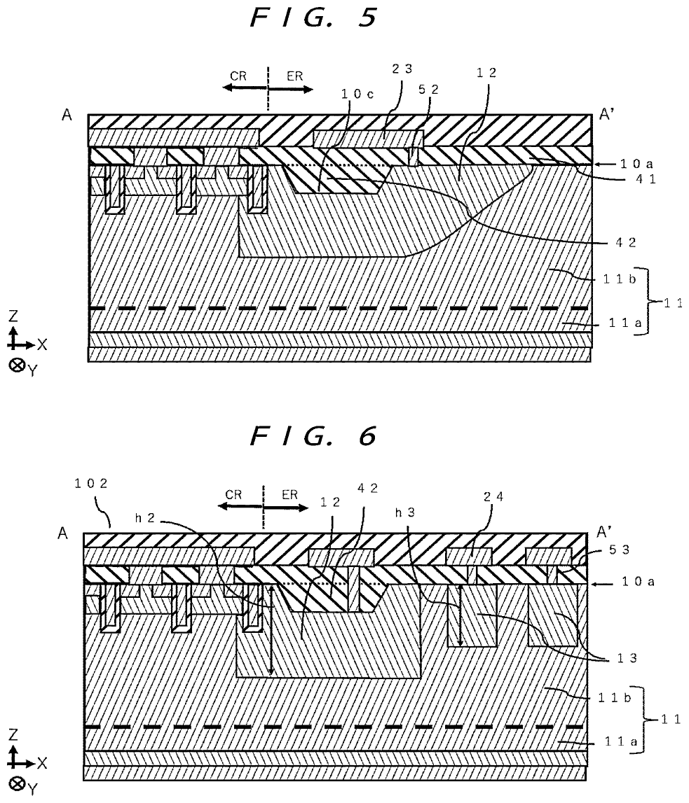

FIGS. 3 to 5 illustrate modifications of the first embodiment. FIG. 3 illustrates a first modification, FIG. 4 illustrates a second modification, and FIG. 5 illustrates a third modification.

First, FIG. 3 illustrating a first modification will be described. According to the first modification illustrated in FIG. 3, the conductive member 50 (first member 40) is provided between the second semiconductor region 12 and the first insulating film 41. That is, FIG. 3 illustrates a case where the first member 40 is formed of a conductive material to form the conductive member 50. The conductive member 50 may contain, for example, polysilicon. The conductive member 50 is formed on the first surface 10c after forming the second semiconductor region 12 by injecting impurities from the first surface 10c, for example.

The second conductive region 52 is not necessarily in contact with the second semiconductor region 12, and may be in contact with the conductive member 50. That is, the third electrode 23 is electrically connected to the second semiconductor region 12 through the second conductive region 52 and the conductive member 50.

In the semiconductor device 101 according to the first embodiment illustrated in FIG. 2, an example in which the insulating member 42 is formed on the first surface 10c has been illustrated, but a conductive material may be provided on the first surface 10c without being limited to an insulating material.

Hereinafter, effects of the semiconductor device 101 according to the first modification illustrated in FIG. 3 will be described. Since the conductive member 50 is provided between the second semiconductor region 12 and the first insulating film 41, it is not necessary to form the second conductive region 52 longer in the Z direction as compared with the semiconductor device 101 according to the first embodiment. The manufacturing efficiency can be improved by simplifying the process of forming the second conductive region 52.

The second conductive region 52 is formed by digging the first insulating film 41 by, for example, etching to form an opening and embedding a conductive material in the opening. As compared with the case where the second conductive region 52 is formed so as to be in contact with the first surface 10c as illustrated in FIG. 2, when the second conductive region 52 is formed so as to be in contact with the conductive member 50 as illustrated in FIG. 3, the aspect ratio of the opening formed by digging the first insulating film 41 is reduced. Here, the aspect ratio is a ratio obtained by dividing the depth of the opening by the width of the opening, and can be rephrased as, for example, a ratio obtained by dividing the length in the Z direction by the length in the X direction in FIG. 3.

The smaller the aspect ratio of the opening, the easier the step of embedding the conductive material by, for example, CVD or the like. That is, it is possible to reduce the risk of defective embedding due to a large aspect ratio. When the second conductive region 52 is in contact with the conductive member 50 as illustrated in FIG. 3, the step of forming the second conductive region 52 is easier than when the second conductive region 52 is formed as illustrated in FIG. 2.

In addition, in order to form the termination region ER short in the X direction, the length of the second semiconductor region 12 in the X direction may be shortened. For example, the area where the second semiconductor region 12 and the first insulating film 41 are in contact with each other on the first main surface 10a is reduced. When the second semiconductor region 12 is formed to be short in the X direction, there is a possibility that the second conductive region 52 has to be formed so as to be in contact with the first surface 10c according to the structure illustrated in FIG. 2. Therefore, it is necessary to embed an opening having a large aspect ratio, which may make the formation of the second conductive region 52 difficult.

On the other hand, according to the structure according to the first modification illustrated in FIG. 3, even when the second semiconductor region 12 is formed to be short in the X direction, the second conductive region 52 reaching the conductive member 50 electrically connected to the second semiconductor region 12 may be formed. Therefore, regardless of the arrangement of the second semiconductor region 12, it is sufficient to form the second conductive region 52 in contact with the conductive member 50 electrically connected to the second semiconductor region 12, so that the design is easy.

As described above, even when the termination region ER is formed to be short in the X direction, the second conductive region 52 can be easily formed according to the semiconductor device according to the first modification illustrated in FIG. 3. That is, by reducing the area of the termination region ER and increasing the area of the cell region CR, it is possible to improve the performance of the semiconductor device.

In addition, as compared with the case where the insulating member 42 is formed as illustrated in FIG. 2, the path of the current flowing through the semiconductor device 101 can be widened by the conductive member 50. Since carriers passing through the second semiconductor region 12 can also pass through the conductive member 50, conductivity is improved. Since the conductivity is improved and the movement of carriers is promoted, the potential of the second semiconductor region 12 is easily stabilized. Since the potential of the second semiconductor region 12 is stabilized, it is possible to stably obtain the effect of enhancing the breakdown resistance or the breakdown voltage of the semiconductor device 101 by the second semiconductor region 12.

In the following description, a case where the insulating member 42 is formed between the semiconductor portion 10 and the first insulating film 41 instead of the conductive member 50 will be described, but the material formed on the first surface 10c is not limited to the insulating material. That is, in the following description, a case where the first member 40 is the insulating member 42 formed of an insulating material will be described, but the first member 40 may be the conductive member 50.

### Second Modification of First Embodiment

Next, FIG. 4 illustrating a second modification will be described. FIG. 4 illustrates an example in which the depth of the second semiconductor region 12 gradually decreases in the termination direction. Here, the gradual decrease in depth means that the second semiconductor region 12 extends longer in the termination direction and the depth decreases continuously or stepwise as compared with the first embodiment illustrated in FIG. 2. Such a structure of the termination region is called a variation of lateral doping (VLD) structure.

In addition, in addition to the shape of the second semiconductor region 12 illustrated in FIG. 4, for example, a portion where the depth of the second semiconductor region 12 is constant in the termination direction may be included in a portion where the depth of the second semiconductor region 12 decreases in the termination direction. Since the portion where the depth of the second semiconductor region 12 is constant in the termination direction is included, the second semiconductor region 12 can extend longer in the termination direction. Since the second semiconductor region 12 extends long in the termination direction, the electric field generated in the semiconductor portion 10 can be dispersed in the termination direction.

The formation of the diffusion layer whose depth gradually decreases in the termination direction illustrated in FIG. 4 can be performed, for example, by changing the ratio of a portion where the resist is provided and a portion where the resist is not provided in the ion implantation step in the termination direction.

Specifically, by increasing the ratio at which the resist is provided in the termination direction, ions can be implanted so that the implantation amount of ions decreases in the termination direction. Alternatively, the amount of ions to be implanted may be reduced in the termination direction by controlling the thickness of the resist.

Up to now, the second modification of the first embodiment illustrated in FIG. 4 has been described. Hereinafter, effects of the semiconductor device illustrated in FIG. 4 will be described. According to the semiconductor device according to the embodiment in FIG. 4, the depth of the second semiconductor region 12 gradually decreases in the termination direction. Due to the second semiconductor region 12 extending while decreasing in depth in the termination direction, the interface between the second semiconductor region 12 and the first semiconductor region 11 extends in the termination direction, as compared with the second semiconductor region 12 illustrated in FIG. 2. By gradually extending the electric field in the termination direction and dispersing points where electric field concentration occurs, it is possible to enhance the breakdown voltage of the semiconductor device 101.

In addition, according to the present embodiment, the necessary length in the termination direction of the termination structure for suppressing the breakdown can be shortened as compared with the case of forming a plurality of guard ring regions divided in the termination direction. By shortening the termination structure, the area of the cell region CR can be made larger relative to the area of the chip, so that the performance of the semiconductor device can be improved. Up to now, the second modification of the semiconductor device 101 according to the first embodiment has been described with reference to FIG. 4.

### Third Modification of First Embodiment

Finally, a third modification of the semiconductor device 101 according to the first embodiment will be described with reference to FIG. 5. In FIG. 5, the electrical connection between the second conductive region 52 and the second semiconductor region 12 is not made on the first surface 10c, but is made on the first main surface 10a.

The second semiconductor region 12 is in contact with the first main surface 10a in the termination direction further than the first surface 10c. The second conductive region 52 penetrates the first insulating film 41 in the Z direction and reaches the first main surface 10a. The second conductive region 52 and the second semiconductor region 12 are electrically connected to each other on the first main surface 10a. The second conductive region 52 is, for example, a metal containing Al.

According to the third modification illustrated in FIG. 5, when forming the second conductive region 52, the opening for embedding the second conductive region 52 only needs to reach the first main surface 10a. Therefore, the depth to be removed by etching may be smaller than that in the second modification illustrated in FIG. 3. Since it is not necessary to perform etching up to the first surface 10c located at a position deeper than the first main surface 10a, the etching efficiency is improved as compared with the second modification. Up to now, the third modification of the semiconductor device 101 according to the first embodiment has been described with reference to FIG. 5.

As described in the first modification, a structure in which the insulating member 42 is formed on the first surface 10c will be described below, but a conductive material such as the conductive member 50 may be formed on the first surface 10c.

In addition, as illustrated in the second modification and the third modification, as long as the third electrode 23 and the second semiconductor region 12 can be electrically connected to each other, the second conductive region 52 may be provided on the first surface 10c as illustrated in FIG. 4, or may be provided on the first main surface 10a as illustrated in FIG. 5.

### Second Embodiment

FIG. 6 is a cross-sectional view illustrating a semiconductor device 102 according to a second embodiment. Description of the same parts as in the first embodiment will be omitted, and different parts will be described.

The semiconductor device 102 according to the present embodiment is different from the semiconductor device 101 according to the first embodiment in the structure of the termination region ER. The semiconductor device 102 includes a third semiconductor region 13 of the second conductivity type.

The third semiconductor region 13 and the second semiconductor region 12 are provided apart from each other. The third semiconductor region 13 is a structure for enhancing the breakdown voltage of the semiconductor device 102 as a guard ring region.

In addition, a fourth electrode 24 electrically connected to the third semiconductor region 13 is formed by the third conductive region 53. The third semiconductor region 13, the third conductive region 53, and the fourth electrode 24 extend in the Y direction, and one third semiconductor region 13, one third conductive region 53, and one fourth electrode 24 are provided in the X direction.

The second semiconductor region 12 and the third semiconductor region 13 are spaced apart from each other in the X direction, and the third semiconductor region 13 is in contact with the first main surface 10a of the semiconductor portion 10.

The third semiconductor region 13 is formed of, for example, a p-type semiconductor and is formed by doping B (boron). The third conductive region 53 and the fourth electrode 24 are formed of, for example, a metal containing Al. The third conductive region 53 and the fourth electrode 24 may be formed of the same material or different materials.

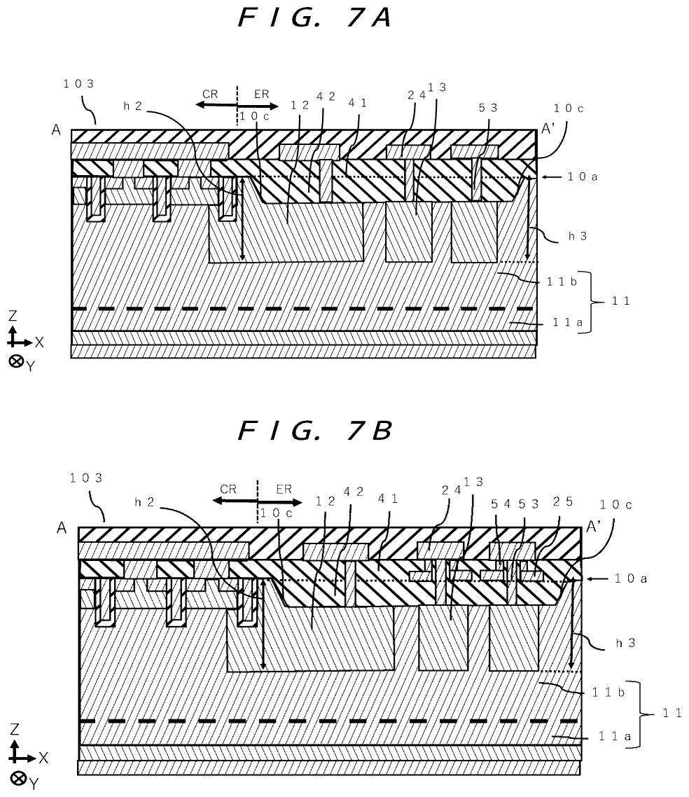

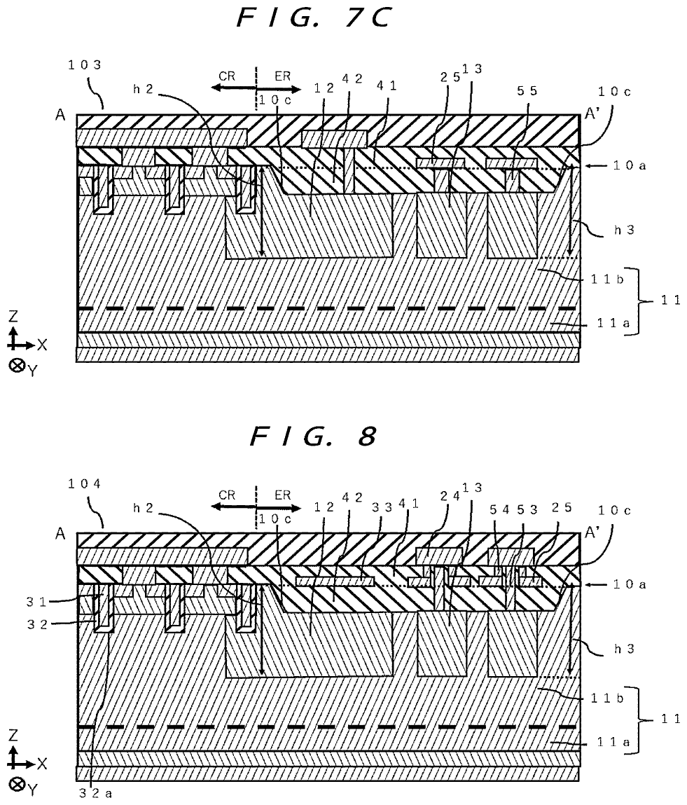

Although two third semiconductor regions 13, two third conductive regions 53, and two fourth electrodes 24 are illustrated in FIG. 7, one third semiconductor region 13, one third conductive region 53, and one fourth electrode 24 may be provided, or three or more third semiconductor regions 13, three or more third conductive regions 53, and three or more fourth electrodes 24 may be provided. The plurality of third semiconductor regions 13 provided have, for example, the same depth h3. That is, the plurality of third semiconductor regions 13 can be formed in the same step.

The depth h3 of the third semiconductor region 13 is smaller than the depth h2 of the second semiconductor region 12, for example. The second semiconductor region 12 and the third semiconductor region 13 can be formed in the same step, for example.

The third semiconductor region 13 is in contact with the first main surface 10a. The depth h3 of the third semiconductor region 13 is smaller than the depth h2 of the second semiconductor region 12, for example. The second semiconductor region 12 and the third semiconductor region 13 are formed by the same step, for example. Even when the second semiconductor region 12 and the third semiconductor region 13 are formed by the same step, since the insulating member 42 is provided between the first main surface 10a and the second semiconductor region 12, the depth measured from the first main surface 10a can be made larger in the second semiconductor region 12.

The third semiconductor region 13 and the fourth electrode 24 are electrically connected to each other through the third conductive region 53. The fourth electrode 24 functions as a field plate, and enhances the breakdown voltage by reducing the electric field inside the semiconductor and prevents charge from accumulating in the interlayer insulating film due to the influence of the external environment to improve reliability.

As described below, by providing the third electrode 23, the second conductive region 52, the fourth electrode 24, and the third conductive region 53, the breakdown voltage of the semiconductor device 102 can be enhanced. On the other hand, even when the third electrode 23, the second conductive region 52, the fourth electrode 24, and the third conductive region 53 are not provided, the third semiconductor region 13 has a predetermined effect of enhancing the breakdown voltage of the semiconductor device 102.

Hereinafter, effects of the semiconductor device 102 according to the present embodiment will be described. According to the semiconductor device 102 according to the present embodiment, since the third semiconductor region 13 is provided, for example, the electric field generated in the semiconductor portion 10 in the off state of the IGBT is dispersed in the third semiconductor region 13 in the termination direction. Therefore, since the concentration of the electric field at the end of the cell region CR is suppressed, the breakdown voltage can be enhanced.

In the structure including the fourth electrode and the third conductive region 53 illustrated in FIG. 6, for example, the electric field generated in the semiconductor portion 10 in the off state of the IGBT can also be dispersed from the third semiconductor region 13 to the fourth electrode 24, so that the breakdown voltage of the semiconductor device 102 can be further enhanced.

In addition, when a plurality of third semiconductor regions 13 are provided, the electric field dispersed in the third semiconductor region 13 in the semiconductor portion 10 is also dispersed in the termination direction between the third semiconductor regions 13. Since the electric field is dispersed in the termination direction over the plurality of third semiconductor regions 13 provided, the breakdown voltage of the semiconductor device 102 can be enhanced.

In addition, similarly to the semiconductor device 101 according to the first embodiment, the breakdown resistance is improved by the second semiconductor region 12. For example, destruction of the semiconductor device 102 can be suppressed by promoting carrier discharge when the IGBT is turned off.

### Third Embodiment

FIGS. 7A, 7B, and 7C are cross-sectional views illustrating a semiconductor device 103 according to a third embodiment.

Description of the same parts as in the first embodiment will be omitted, and different parts will be described.

The semiconductor device 103 according to the present embodiment is different from the second embodiment in that the entire third semiconductor region 13 is provided below the insulating member 42. The insulating member 42 is located between the first insulating film 41 and the first surface 10c. The insulating member 42 is provided so as to be in contact with the second semiconductor region 12 and the third semiconductor region 13.

The depth h3 of the third semiconductor region 13 is common to, for example, the plurality of third semiconductor regions 13 provided. The third semiconductor region 13 having the common depth h3 can be formed in the same step. In addition, h2 and h3 are, for example, the same. The second semiconductor region 12 and the third semiconductor region 13 can be formed in the same step.

The third conductive region 53 penetrates the first insulating film 41 and the insulating member 42 and is in contact with the third semiconductor region 13. The fourth electrode 24 and the third semiconductor region 13 face each other with the first insulating film 41 and the insulating member 42 interposed therebetween, and are electrically connected to each other by the third conductive region 53. The fourth electrode and the third conductive region 53 are formed of, for example, a metal containing Al.

Up to now, the semiconductor device 103 according to the third embodiment has been described with reference to FIG. 7A.

FIGS. 7B and 7C illustrate cases where the structures of the electrode and the conductive region provided in the third semiconductor region 13 are different from those in FIG. 7A. First, FIG. 7B will be described.

In FIG. 7B, the fourth electrode 24 is provided on the first insulating film 41, and the fifth electrode 25 is provided between the insulating member 42 and the first insulating film 41. A third conductive region 53 that electrically connects the third semiconductor region 13 and the fourth electrode 24 to each other is provided, and a fourth conductive region 54 that connects the fourth electrode 24 and the fifth electrode 25 to each other is provided.

The fifth electrode 25 is electrically connected to the third semiconductor region 13 through the fourth conductive region 54, the fourth electrode 24, and the third conductive region 53.

According to the structure illustrated in FIG. 7B, the electric field generated in the semiconductor portion 10 can also be dispersed between the fifth electrode 25 and the third semiconductor region 13. The fifth electrode 25 is formed of, for example, polysilicon.

Next, FIG. 7C will be described. In FIG. 7C, the fifth electrode 25 is provided between the first insulating film 41 and the insulating member 42, and is electrically connected to the third semiconductor region 13 by the fifth conductive region 55. For example, the fifth conductive region 55 is formed after the insulating member 42 is formed, and the fifth electrode 25 is formed so as to cover the fifth conductive region 55. Then, the first insulating film 41 is formed.

The structure illustrated in FIG. 7C also makes it possible to disperse the electric field generated in the semiconductor portion 10 from the third semiconductor region 13 to the fifth electrode 25. The fifth electrode 25 is formed of, for example, polysilicon. The fifth conductive region 55 is formed of, for example, a metal containing Al.

As illustrated in FIG. 7C, providing the fifth electrode 25 between the first insulating film 41 and the insulating member 42 and connecting the fifth electrode 25 to the third semiconductor region 13 do not necessarily require the fourth electrode 24.

In FIG. 7A, 7B, or 7C described above, the structure in which the insulating member 42 is provided between the first insulating film 41 and the third semiconductor region 13 to disperse the electric field above the third semiconductor region 13 is common.

Hereinafter, effects of the semiconductor device 103 according to the present embodiment will be described. According to the semiconductor device 103 according to the present embodiment, the third semiconductor region 13 formed on the first surface 10c is in contact with the insulating member 42 unlike the semiconductor device 102 according to the second embodiment. The third semiconductor region 13 is provided below the first surface 10c. Therefore, the diffusion length of the dopant in the Z direction necessary for forming the third semiconductor region 13 in the semiconductor device 103 is smaller than that in the semiconductor device 102 according to the second embodiment with the third semiconductor region 13 having the same depth as in the semiconductor device 103.

As compared with the semiconductor device 102 according to the second embodiment, the semiconductor device 103 according to the present embodiment has a structure in which the depth h3 of the third semiconductor region 13 is equal to the sum of the thickness of the insulating member 42 in the Z direction and the thickness of the third semiconductor region 13 in the Z direction.

Therefore, the required amount of the diffusion length of the dopant is smaller than that in the semiconductor device 102 according to the second embodiment.

In other words, in the semiconductor device 103 according to the present embodiment, it is possible to form the deeper third semiconductor region 13 even with a shorter diffusion length of the dopant as compared with the semiconductor device 102 according to the second embodiment. Since the third semiconductor region 13 having the same depth as the second semiconductor region 12 can be formed by annealing treatment at a temperature lower than that in the case of the structure illustrated in the semiconductor device 102 according to the second embodiment, defects of the Si wafer can be further suppressed.

In addition, since the third semiconductor region 13 is formed in the same step as the second semiconductor region 12, for example, the third semiconductor region 13 having h3 having the same depth as h2 can be obtained. By forming the third semiconductor region 13 deeper than in the case of the semiconductor device 102 according to the second embodiment, dispersion of the electric field to the third semiconductor region 13 is promoted in the semiconductor portion 10. That is, the third semiconductor region 13 can be formed by the low-temperature annealing treatment, and the breakdown voltage of the semiconductor device 103 can be enhanced.

### Fourth Embodiment

FIG. 8 is a cross-sectional view illustrating a semiconductor device 104 according to a fourth embodiment. Description of the same parts as in the third embodiment will be omitted as appropriate.

The semiconductor device 104 according to the present embodiment includes a gate wiring portion 33 on the insulating member 42 in the termination region ER. The gate wiring portion 33 is electrically connected to at least one of the plurality of gate electrodes 31 formed in the cell region CR. Here, in FIG. 8, the gate wiring portion 33 is not connected to the gate electrode 31, but is electrically connected to the gate electrode 31 in a cross section different from the cross section illustrated in FIG. 8, for example.

That is, in the top view illustrated in FIG. 1, for example, the gate wiring portion 33 is formed so as to surround the cell region CR, but FIG. 8 merely illustrates a cross section in a direction in which the cell region CR and the termination region ER are adjacent to each other in the X direction. The gate wiring portion 33 may be electrically connected to at least a part of the gate electrode 31 in a cross section different from that in FIG. 8, for example, in a direction in which the cell region CR and the termination region ER are adjacent to each other in the Y direction.

The gate wiring portion 33 is formed of, for example, a metal containing Al. The gate wiring portion 33 may be formed in the same step as the fifth electrode 25, for example.

Although FIG. 8 illustrates a case where only the gate wiring portion 33 is formed above the second semiconductor region 12, a field plate may be further provided as illustrated in FIG. 7 in addition to the gate wiring portion 33. In the XZ plane, both the gate wiring portion 33 and the field plate may be formed, or the gate wiring portion 33 may be formed in a part of the termination region ER surrounding the cell region CR and the field plate may be formed in a part thereof.

Hereinafter, effects of the semiconductor device 104 according to the present embodiment will be described. According to the semiconductor device 104 according to the present embodiment, the gate wiring portion 33 is formed on the insulating member 42 to control the voltage of the gate electrode 31. By forming the gate wiring portion 33 above the second semiconductor region 12 in the termination region, it is not necessary to form the gate wiring portion 33 in the cell region CR. For example, since the emitter electrode of the IGBT can be widely formed in the cell region CR, the on-resistance can be reduced.

In addition, the gate wiring portion 33 on the insulating member 42 can be formed by, for example, the same step as the step of forming the fifth electrode 25 on the third semiconductor region 13. That is, according to the semiconductor device 104 according to the present embodiment, since the gate wiring portion 33 is arranged in the termination region ER, the wiring on the first main surface 10a can be efficiently formed. Therefore, the performance of the semiconductor device 104 can be improved.

### Fifth Embodiment

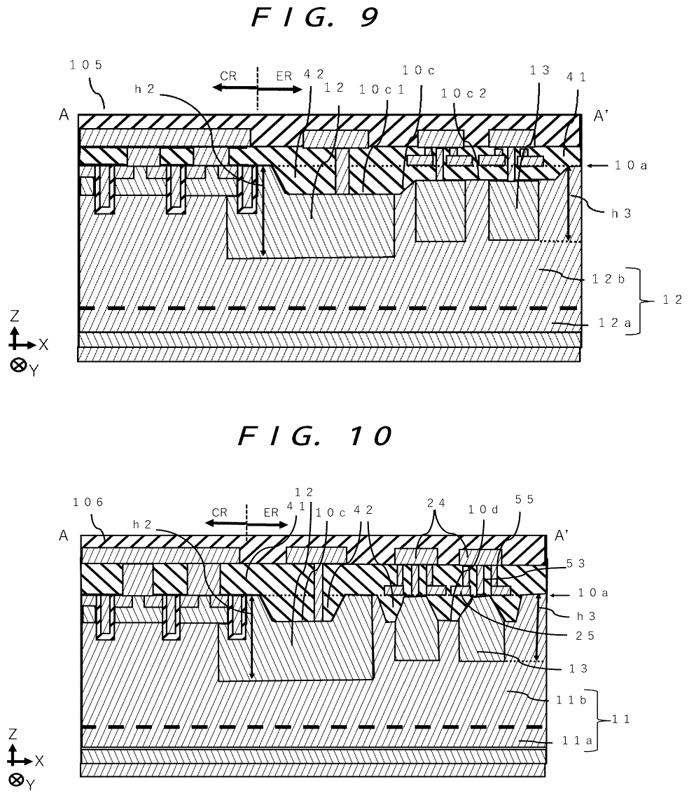

FIG. 9 is a cross-sectional view illustrating a semiconductor device 105 according to a fifth embodiment. Description of the same parts as in the third embodiment will be omitted as appropriate.

In the semiconductor device 105 according to the present embodiment, the first surface 10c formed below the insulating member 42 has a plurality of bottom portions. The bottom portion is a portion at least a part of which is parallel to the first main surface 10a. The plurality of bottom portions include a first bottom portion 10cl and a second bottom portion 10c2. The second semiconductor region 12 is in contact with the first bottom portion 10c1, and the third semiconductor region 13 is in contact with the second bottom portion 10c2.

For example, the first bottom portion 10cl is formed deeper than the second bottom portion 10c2. Then, the second semiconductor region 12 provided below the first bottom portion 10cl is formed deeper than the third semiconductor region 13 provided below the first bottom portion 10cl. For example, the second semiconductor region 12 and the third semiconductor region 13 are formed in the same step. In other words, the second semiconductor region 12 and the third semiconductor region 13 may be simultaneously formed by a step of forming the diffusion layer. Since the first bottom portion 10cl is formed deeper than the second bottom portion 10c2, h2 can be made larger than h3 even when the second semiconductor region 12 and the third semiconductor region 13 are formed in the same step.

The number of bottom portions of the first surface 10c may be three or more. For example, a plurality of third semiconductor regions 13 provided in bottom portions having different depths may be included in the third semiconductor region 13. By providing a plurality of bottom portions on the first surface 10c, a plurality of third semiconductor regions 13 having different depths can be formed in the same step. A structure can be adopted in which the depths of the plurality of third semiconductor regions 13 are made different from each other and the depth of the third semiconductor region 13 decreases in the termination direction.

In addition, as illustrated in FIG. 9, it is also possible to adopt a VLD structure in which the third semiconductor region 13 is omitted and the second semiconductor region 12 is extended in the termination direction, even though the plurality of third semiconductor regions 13 provided is a desirable structure for suppressing electric field concentration. That is, it is possible to provide the second semiconductor region 12 as a single diffusion layer over the first surface 10c having a plurality of bottom portions. By controlling the depth of the plurality of bottom portions provided, for example, the second semiconductor region 12 whose depth decreases in the termination direction can be formed by a single step.

Hereinafter, effects of the semiconductor device 105 according to the present embodiment will be described. According to the semiconductor device 105 according to the present embodiment, although it is necessary to add a step for the step of providing a plurality of bottom portions, for example, the first bottom portion 10cl and the second bottom portion 10c2 on the first surface 10c, the second semiconductor region 12 and the third semiconductor region 13 can be formed in the same step. In addition, the difference between the depth h2 of the second semiconductor region 12 and the depth h3 of the third semiconductor region 13 can be controlled by the difference in depth between the first bottom portion 10cl and the second bottom portion 10c2 of the first surface 10c.

The difference between h2 and h3 can be controlled in the step of forming the first surface 10c. In other words, the diffusion of the dopant for forming the second semiconductor region 12 and the diffusion of the dopant for forming the third semiconductor region 13 can be performed in the same step. The depths h2 and h3 can be made different from each other without adding a new step in the step of forming the diffusion layer. In the semiconductor device 103 according to the third embodiment illustrated in FIG. 7, in order to make the depths of the second semiconductor region 12 and the third semiconductor region 13 different, it is necessary to divide the formation of the diffusion layer into two or more steps. On the other hand, according to the semiconductor device 105 according to the present embodiment, the diffusion layer can be formed in the same step.

### Sixth Embodiment

FIG. 10 is a cross-sectional view illustrating a semiconductor device 106 according to a sixth embodiment.

Description of the same parts as in the fifth embodiment will be omitted as appropriate.

The semiconductor device 106 illustrated in FIG. 10 includes a second surface 10d formed apart from the first surface 10c in addition to the first surface 10c. The second surface 10d is a surface including an interface between the insulating member 42 and the third semiconductor region 13. Making the first surface 10c and the second surface 10d apart from each other means that the first main surface 10a is interposed between the first surface 10c and the second surface 10d. In other words, between the first surface 10c and the second surface 10d formed by digging the first main surface 10a, the first main surface 10a that remains undigged is interposed. A plurality of second surfaces 10d may be provided while divided in the X direction.

At least a part of the second surface 10d may have a bottom portion parallel to the first main surface 10a. The shape of the second surface 10d is not limited to the shape illustrated in FIG. 10, and may be, for example, a bowl shape.

The second semiconductor region 12 is a diffusion layer provided so as to be in contact with the first surface 10c, and the third semiconductor region 13 is a diffusion layer provided so as to be in contact with the second surface 10d.

The plurality of second surfaces 10d are formed in the same step, for example. For the first surface 10c and the second surface 10d, the first surface 10c and the second surface 10d can be formed by performing etching in two separate steps at most. It is not necessary to increase the number of etching steps as compared with the fifth embodiment.

The insulating member 42 is provided between the first surface 10c and the first insulating film 41 and between the second surface 10d and the first insulating film 41. The insulating member 42 refers to all of a plurality of insulating films provided to be divided in the X direction as illustrated in FIG. 10.

At least a part of the second surface 10d is in contact with the third semiconductor region 13. For example, the second surface 10d is partially in contact with the third semiconductor region 13 and partially in contact with the first semiconductor region 11. The second surface 10d may be formed across a plurality of divided third semiconductor regions 13.

The fifth electrode 25 is provided on the insulating member 42. The fifth electrode 25 faces the second surface 10d with the insulating member 42 interposed therebetween. The fifth electrode 25 is formed of, for example, polysilicon.

The depth h2 of the second semiconductor region 12 is larger than the depth h3 of the third semiconductor region 13. The second semiconductor region 12 and the third semiconductor region 13 are formed by the same step, for example.

Hereinafter, effects of the semiconductor device 106 according to the present embodiment will be described. The semiconductor device 106 according to the present embodiment includes the second surface 10d formed apart from the first surface in addition to the first surface 10c. By forming the insulating member 42 and the fifth electrode 25 on the second surface 10d, the breakdown voltage can be enhanced. In addition, the first main surface 10a and the third semiconductor region 13 are partially in contact with each other, and the third semiconductor region 13, which has a different depth from the second semiconductor region 12 in contact with the first surface 10c, can be formed in the same step as the step of forming the second semiconductor region 12.

The second semiconductor region 12 is mainly formed of impurities injected from the first surface 10c. On the other hand, the third semiconductor region 13 is mainly formed of impurities injected from the first main surface 10a. Therefore, the second semiconductor region 12 can be formed deeper while the second semiconductor region 12 and the third semiconductor region 13 are formed in the same step including impurity injection.

In addition, a structure in which the fifth electrode 25 faces the second surface 10d in the Z direction with the insulating member 42 interposed therebetween is possible. The second surface 10d is in contact with the third semiconductor region 13, and the fifth electrode 25 functions as a field plate, and enhances the breakdown voltage by reducing the electric field inside the semiconductor and prevents charge from accumulating in the interlayer insulating film due to the influence of the external environment to improve reliability.

That is, according to the semiconductor device 106 according to the present embodiment, the following effects can be obtained. First, the electric field can be dispersed by the fifth electrode 25 to enhance the breakdown voltage of the semiconductor device 106. In addition, the insulating member 42 is formed by digging the first semiconductor region 11, and the fifth electrode 25 is formed on the insulating member 42. Therefore, as compared with a case where an insulating film is formed on the first main surface 10a and an electrode is further formed on the insulating film, the step in the Z direction between the cell region CR and the termination region ER is reduced, which is advantageous in a process such as lithography.

According to the semiconductor device of at least one of the first to sixth embodiments described above, the depth h2 of the second semiconductor region 12 provided below the first surface 10c can be made larger than the depth h1 of the gate insulating film 32 of the cell region CR. Since the bottom surface 32a of the gate insulating film 32 and the second semiconductor region 12 are in contact with each other, it is possible to suppress the concentration of an electric field on the bottom surface 32a, and it is possible to enhance breakdown resistance by forming a carrier discharge path. In addition, since the second semiconductor region 12 in contact with the bottom surface 32a can be formed by low-temperature and short-time annealing treatment, it is possible to suppress a decrease in reliability due to defects generated in the Si wafer and to improve manufacturing efficiency.

Hereinafter, a method of manufacturing a semiconductor device will be described.

A semiconductor device manufacturing method according to an embodiment includes: a step of forming a first surface by selectively digging a first main surface of a semiconductor portion; a step of forming a second semiconductor region of a second conductivity type by injecting impurities into a first semiconductor region of a first conductivity type of the semiconductor portion from the first surface and performing annealing treatment; a step of forming a first member on the first surface; a step of forming a gate insulating film, which has a bottom surface at least partially in contact with the second semiconductor region, in the first semiconductor region from the first main surface; a step of forming a gate electrode covered with the gate insulating film; and a step of forming a first insulating film on the first main surface.

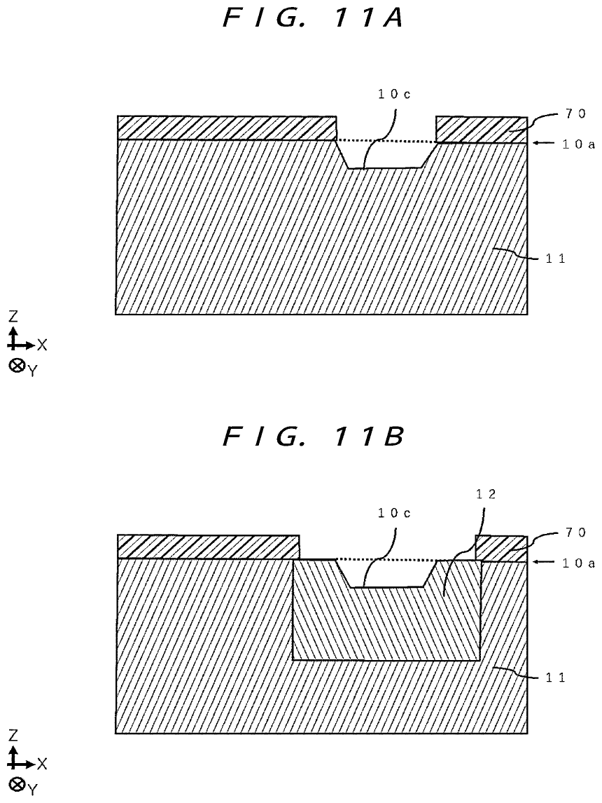

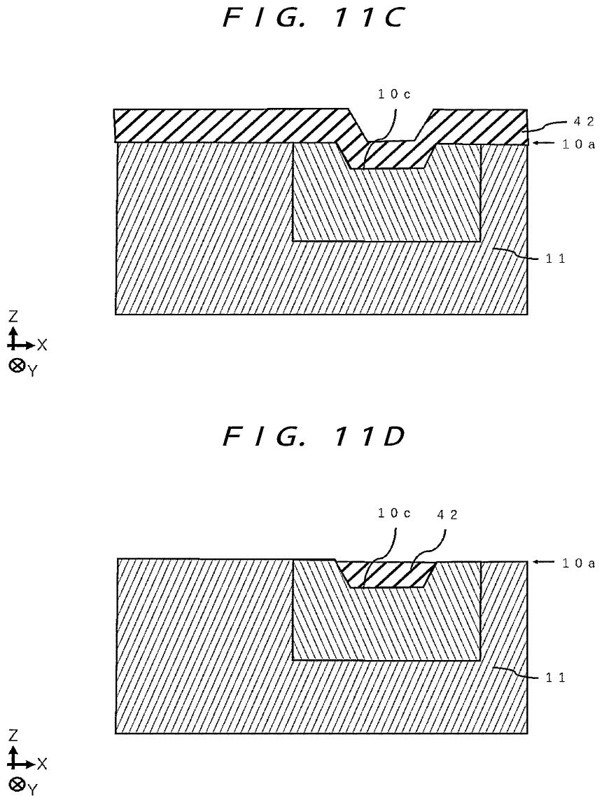

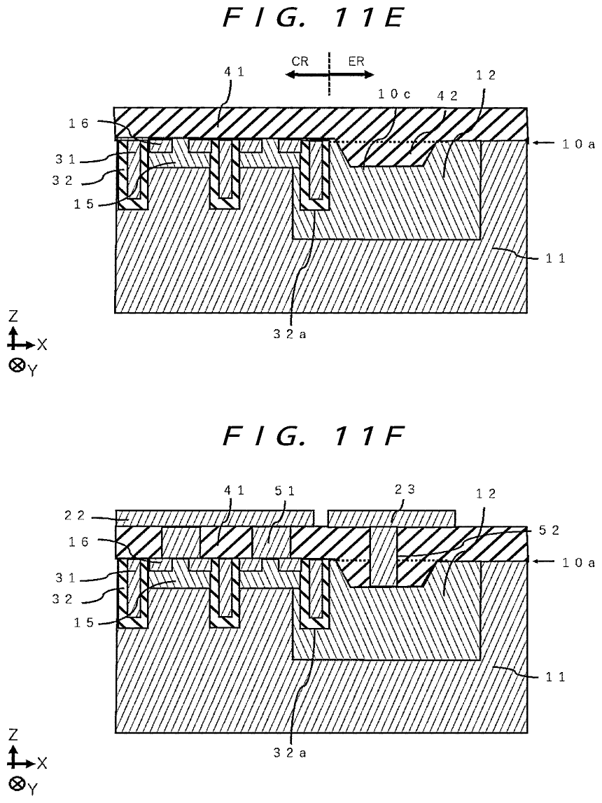

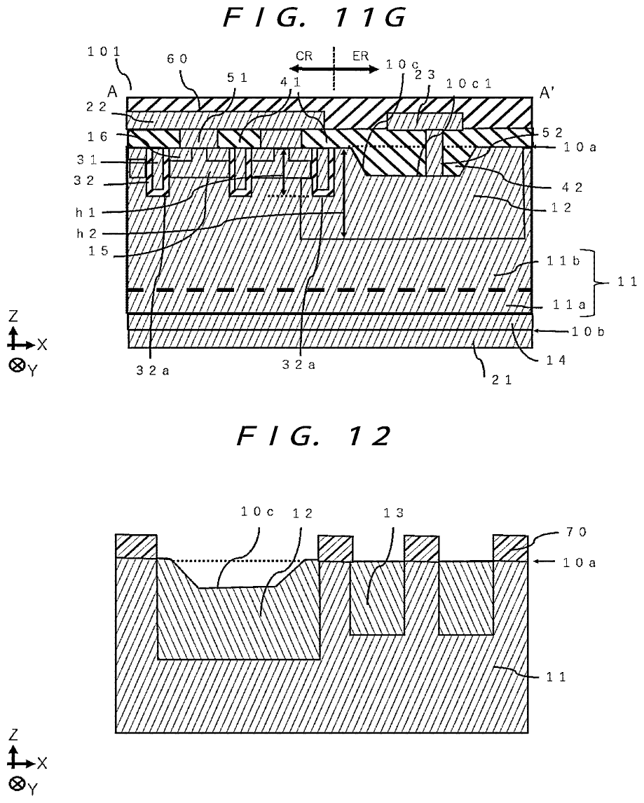

First, a method of manufacturing the semiconductor device 101 according to the first embodiment will be described with reference to FIGS. 11A to 11G. Since the configuration of the cell region CR is not largely different from that of a general semiconductor device, a part of the description will be omitted. The cell region CR is formed, for example, in parallel with the step of manufacturing the termination region ER. For example, an IGBT is formed in the cell region CR.

First, as illustrated in FIG. 11A, a resist 70 is selectively provided on the first main surface 10a of the semiconductor portion 10. Then, in a portion where the resist 70 is not provided, the first surface 10c is formed by digging a part of the first semiconductor region 11 from the first main surface 10a toward the negative direction in the Z direction. The first surface 10c is a bottom surface of a recess formed by etching the first semiconductor region 11 using a method including, for example, any of RIE, wet etching, or chemical dry etching (CDE). The first surface 10c may have a shape illustrated in FIG. 11A or a bowl shape.

Subsequently, a part or entirety of the resist 70 illustrated in FIG. 11A is removed, and as illustrated in FIG. 11B, the resist 70 is provided again, and the second semiconductor region 12 is formed in the first semiconductor region 11 from a surface including at least a part of the first surface 10c. The second semiconductor region 12 is, for example, a diffusion layer formed of a p-type semiconductor, and is formed in the first semiconductor region 11 formed of an n-type semiconductor. The second semiconductor region 12 is formed by injecting and diffusing boron (B), for example. The method for diffusing the dopant is, for example, annealing treatment.

Then, as illustrated in FIG. 11C, an insulating member 42 is formed on the first main surface 10a and the first surface 10c of the semiconductor portion 10. The insulating member 42 is formed by, for example, chemical vapor deposition (CVD). The insulating member 42 is an oxide film containing silicon oxide, such as SiO₂. The insulating member 42 is formed at least in a portion where the semiconductor portion 10 is dug and removed when the first surface 10c is formed.

Then, as illustrated in FIG. 11D, the excess insulating member 42 is removed. The step of removing the excess portion of the insulating member 42 is performed by, for example, wet etching. A portion remaining on at least the first surface 10c without being removed is referred to as an insulating member 42 again. Although FIG. 11D illustrates a state in which the insulating member 42 does not remain on the first main surface 10a, the insulating member 42 may also remain on the first main surface 10a. In this manner, the insulating member 42 having the structure illustrated in FIG. 2 is obtained.

Subsequently, as illustrated in FIG. 11E, in the cell region CR, for example, the fifth semiconductor region 15 and the sixth semiconductor region 16 are formed as illustrated in FIG. 11E.

The fifth semiconductor region 15 is a p-type diffusion layer formed by injecting boron, for example. The sixth semiconductor region 16 is an n-type emitter region formed by selectively injecting, for example, phosphorus on the fifth semiconductor region 15.

After the fifth semiconductor region 15 and the sixth semiconductor region 16 are formed, the semiconductor portion 10 is dug to form the gate insulating film 32 and the gate electrode 31. The gate insulating film 32 is, for example, an oxide film containing silicon oxide, and is formed by CVD in a portion dug by CDE. The gate electrode 31 is formed of, for example, polysilicon.

In the gate insulating film 32, the bottom surface 32a of the gate insulating film 32 closest to the termination region ER is in contact with the second semiconductor region 12 already formed in the previous step at least partially. For example, the entire bottom surface 32a may be in contact with the second semiconductor region 12.

When digging the semiconductor portion 10 to form the gate insulating film 32 closest to the termination region ER, a portion of the semiconductor portion 10 including at least the already formed second semiconductor region 12 is dug. Therefore, the gate insulating film 32 is in contact with the second semiconductor region 12.

After the structure including the gate electrode 31 and the gate insulating film 32 is formed in the cell region CR, the first insulating film 41 is provided over the cell region CR and the termination region ER on the first main surface 10a of the semiconductor portion 10 and the insulating member 42. The first insulating film 41 is an oxide film containing silicon oxide, such as SiO₂.

Then, as illustrated in FIG. 11F, the second conductive region 52 is formed in the termination region ER. This step is performed by selectively digging the first insulating film 41 and the insulating member 42 and embedding a conductive material. The first insulating film 41 and the insulating member 42 are selectively removed by, for example, reactive ion etching (RIE). The conductive material is, for example, a metal containing Al. The conductive material is provided by, for example, sputtering or chemical vapor deposition (CVD).

The third electrode 23 is provided on the first insulating film 41. The third electrode 23 is formed by sputtering, for example. The second conductive region 52 and the third electrode 23 may be formed of a material having the same conductivity type, or may be formed of different materials. The third electrode 23 is formed of, for example, a metal containing Al.

In addition, the first conductive region 51 of the cell region CR illustrated in FIG. 11F can be formed in the same step as the step of forming the second conductive region 52 after forming the first insulating film 41. The second electrode 22 in the cell region CR illustrated in FIG. 11G can be formed in the same step as the step of forming the third electrode 23.

FIG. 11G illustrates the structure of FIG. 11F without omitting the structure on the second main surface 10b side. For example, a structure on the second main surface 10b side is formed as follows, and the IGBT is formed in the cell region CR.

The fourth semiconductor region 14 is formed on the second main surface 10b opposite to the first main surface 10a. The fourth semiconductor region 14 is, for example, a collector region obtained by injecting B (boron) from the second main surface 10b. Then, the first electrode 21 is provided on the second main surface 10b. The first electrode 21 has a structure common to the cell region CR and the termination region ER. When the IGBT is formed in the cell region CR, the first electrode 21 is a collector electrode, and the second electrode 22 is an emitter electrode.

At least a part of the second electrode 22 or the third electrode 23 provided on the first main surface 10a is covered with a protective film 60. The protective film 60 is formed by applying polyimide, for example. Up to now, the method of manufacturing the semiconductor device 101 according to the first embodiment has been described with reference to FIGS. 11A to 11G.

Then, a method of manufacturing the semiconductor device 102 according to the second embodiment will be described with reference to FIG. 12. In addition, portions different from the method of manufacturing the semiconductor device 101 according to the first embodiment illustrated in FIGS. 11A to 11G will be mainly described. FIG. 12 illustrates a step of injecting a dopant for forming the second semiconductor region 12 and the third semiconductor region 13.

The step illustrated in FIG. 12 is different from the step of injecting the dopant illustrated in FIG. 11B in the position where the resist 70 is provided. A plurality of portions where the resist 70 is not provided are provided in the X direction. The resist 70 is not formed on at least a part of the first surface 10c. In addition, a part of the first main surface 10a is not covered with the resist 70 in the termination direction from the first surface 10c.

Impurities are injected into the first semiconductor region 11 from a portion where the resist 70 is not provided, thereby forming the second semiconductor region 12 and the third semiconductor region 13. The second semiconductor region 12 and the third semiconductor region 13 are, for example, p-type diffusion layers formed in the n-type first semiconductor region 11. The second semiconductor region 12 and the third semiconductor region 13 can be formed by the same diffusion layer forming process.

The step of providing the insulating member 42 or the first insulating film 41 after forming the second semiconductor region 12 and the third semiconductor region 13 is similar to that in FIG. 11, and accordingly the description thereof will be omitted.

However, the third conductive region 53 illustrated in FIG. 6 is formed in the same step as the second conductive region 52, for example. The fourth electrode 24 illustrated in FIG. 6 is formed in the same step as the third electrode 23, for example. Up to now, the method of manufacturing the semiconductor device 103 according to the third embodiment has been described with reference to FIG. 12.

Next, a step of forming the third semiconductor region 13 in the method of manufacturing the semiconductor device 103 according to the third embodiment will be described with reference to FIG. 13. As illustrated in FIG. 13, the second semiconductor region 12 and the third semiconductor region 13 can be formed on the first surface 10c by providing a plurality of portions where the resist 70 is not provided on the first surface 10c. The second semiconductor region 12 and the third semiconductor region 13 can be obtained by the same step. Impurities injected to form the second semiconductor region 12 and the third semiconductor region 13 can be injected simultaneously. The structure of the semiconductor device 103 according to the third embodiment illustrated in FIG. 7A, 7B, or 7C can be obtained by the method for forming a diffusion layer illustrated in FIG. 13.

In addition, the step of forming the third conductive region 53 illustrated in FIG. 7A can be performed simultaneously with the step of forming the second conductive region 52 on the second semiconductor region 12, for example. The step of forming the fourth electrode 24 illustrated in FIG. 7A can be performed simultaneously with the step of forming the third electrode 23, for example. The third conductive region 53 is formed of, for example, a metal containing Al. The third conductive region 53 is formed, for example, by digging the first insulating film 41 and the insulating member 42 by CDE and embedding a conductive material by CVD. The fourth electrode 24 is formed by sputtering, for example. The fourth electrode 24 is formed of, for example, the same material as the third conductive region 53.

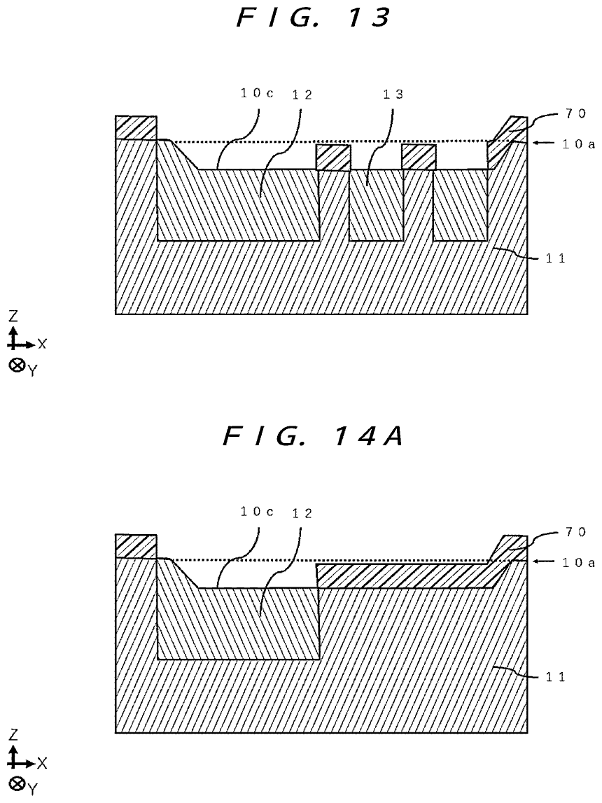

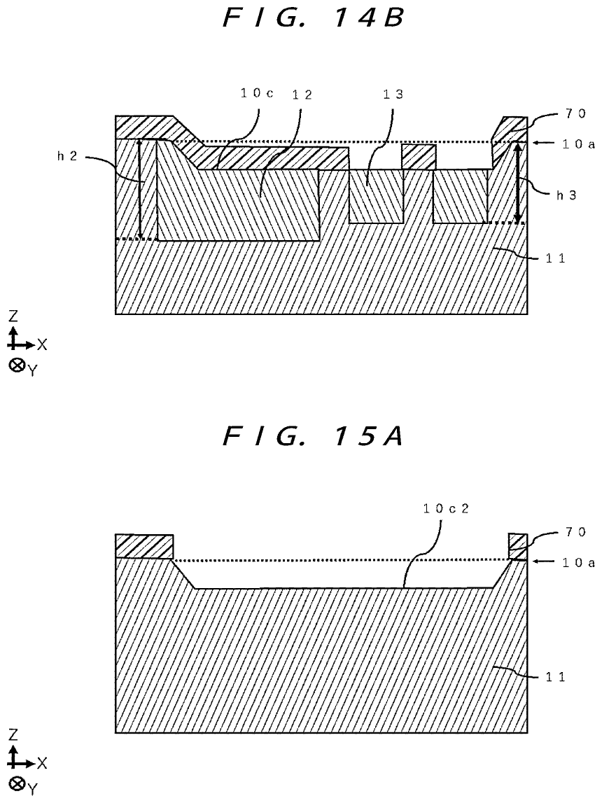

Next, an example of a method will be described with reference to FIGS. 14A and 14B, in which the depths of the second semiconductor region 12 and the third semiconductor region 13 of the semiconductor device 103 according to the third embodiment are made different. FIG. 14A illustrates a process of forming the second semiconductor region 12. FIG. 14B illustrates a step of forming the third semiconductor region 13.

First, as illustrated in FIG. 14A, the resist 70 is provided.

The second semiconductor region 12 is formed by injecting impurities into a portion where the resist 70 is not provided.

Subsequently, a part or entirety of the resist 70 illustrated in FIG. 14A is removed, and the resist 70 is provided again as illustrated in FIG. 14B. The third semiconductor region 13 is formed by injecting impurities from a portion where the resist 70 is not provided. The acceleration voltage when injecting impurities in the step illustrated in FIG. 14B can be different from the acceleration voltage in the step of FIG. 14A. As the acceleration voltage at the time of injection increases, the impurities can reach deeper in the first semiconductor region 11. That is, the depth of the diffusion layer formed by the step in FIG. 14A and the depth of the diffusion layer formed by the step in FIG. 14B can be different. The depth h2 of the second semiconductor region 12 and the depth h3 of the third semiconductor region 13 can be different.

For example, FIG. 14B illustrates a case where h2 is formed to be larger than h3. In FIG. 14B, the resist 70 covers the second semiconductor region 12, but the second semiconductor region 12 does not need to be covered with the resist 70. In the second semiconductor region 12 where impurities have already been injected in FIG. 14A, impurities may also be injected in the step illustrated in FIG. 14B. Even if impurities are further injected into the second semiconductor region 12 in the step of FIG. 14B, the magnitude relationship in which h2 is larger than h3 is maintained.

In addition, h3 can be made larger than h2. For example, it is possible to form the third semiconductor region 13 first and then form the second semiconductor region 12 shallower than the third semiconductor region 13. By performing the step of injecting impurities in two or more separate steps, the depths of the second semiconductor region 12 and the third semiconductor region 13 can be made different from each other.

Up to now, an example of the method in which the depths of the second semiconductor region 12 and the third semiconductor region 13 of the semiconductor device 104 according to the fourth embodiment are made different has been described with reference to FIGS. 14A and 14B.

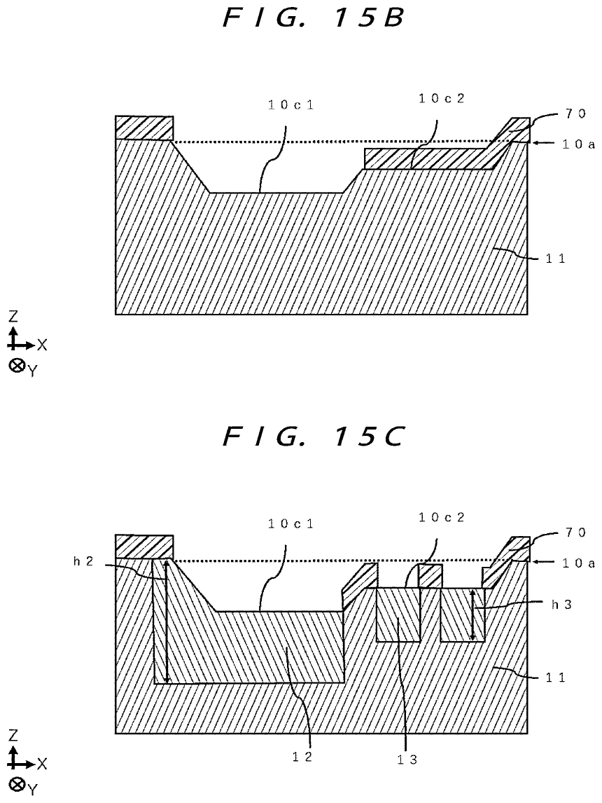

Next, a method of manufacturing the semiconductor device 105 according to the fifth embodiment will be described with reference to FIGS. 15A, 15B, and 15C. In addition, the step of providing the first surface 10c having a plurality of bottom portions will be described in detail, and the rest of the description will be omitted since the rest of the description is the same as the previous description.

As illustrated in FIG. 15A, the second bottom portion 10c2 is formed by providing the resist 70 on the first main surface 10a and performing etching.

Subsequently, a part or entirety of the resist 70 illustrated in FIG. 15A is removed, and the resist 70 is provided again as illustrated in FIG. 15B. By selectively removing the first semiconductor region 11 in a portion where the resist 70 is not provided, the first bottom portion 10cl deeper than the second bottom portion 10c2 is formed.

Then, a part or entirety of the resist 70 illustrated in FIG. 15B is removed, and the resist 70 is provided again as illustrated in FIG. 15C to form the second semiconductor region 12 and the third semiconductor region 13. The second semiconductor region 12 and the third semiconductor region 13 can be formed by the same step. Since the first bottom portion 10cl and the second bottom portion 10c2 have different depths, the depth h2 of the second semiconductor region 12 and the depth h3 of the third semiconductor region 13 can be made different.

The second semiconductor region 12 is in contact with the first bottom portion 10c1, and the third semiconductor region 13 is in contact with the second bottom portion 10c2. For example, when the first bottom portion 10cl is provided deeper than the second bottom portion 10c2, the depth h2 of the second semiconductor region 12 can be made larger than the depth h3 of the third semiconductor region 13.

According to the method of manufacturing a semiconductor device illustrated in FIGS. 15A, 15B, and 15C, the difference between the depth h2 of the second semiconductor region 12 and the depth h3 of the third semiconductor region 13 can be controlled by the difference in the depth of the first bottom portion 10cl or the second bottom portion 10c2 of the first surface 10c provided on the first main surface 10a. In addition, it is also possible to form the second semiconductor region 12 and the third semiconductor region 13 in the same step. Up to now, the method of manufacturing the semiconductor device according to the fifth embodiment has been described with reference to FIGS. 15A, 15B, and 15C.

In addition, the step of providing the first surface 10c having a plurality of bottom portions can be performed by, for example, the following step (not illustrated) in addition to the step illustrated in FIG. 15. In addition, a case where the first bottom portion 10cl is deeper than the second bottom portion 10c2 will be described.

First, a portion other than a portion where the first bottom portion 10cl is to be provided is covered with the resist 70, and the first semiconductor region 11 is etched. Then, the second bottom portion 10c2 is formed by performing etching shallower than in the previous step without covering the portion where the second bottom portion 10c2 is to be provided with the resist 70. In the step of forming the second bottom portion 10c2, the portion where the first bottom portion 10cl is formed may be covered with a resist or may not be covered. As described above, a plurality of bottom portions having different depths can also be formed by the method of forming the deeper bottom portion first.

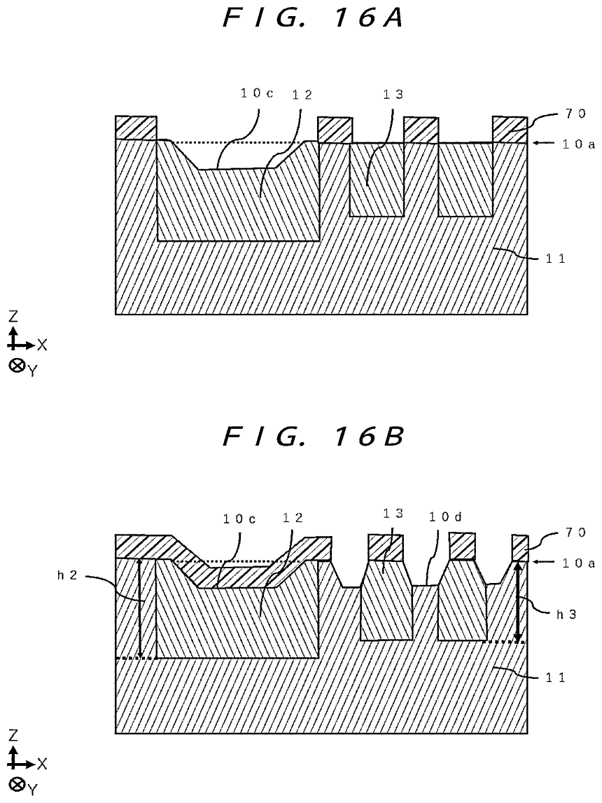

Finally, a method of manufacturing the semiconductor device 106 according to the sixth embodiment illustrated in FIG. 10 will be described with reference to FIGS. 16A and 16B. FIG. 16A illustrates a step of forming the first surface 10c to form the second semiconductor region 12 and the third semiconductor region 13. FIG. 16B illustrates a step of forming the second surface 10d.

First, in FIG. 16A, the step of forming the first surface 10c is omitted. The first surface 10c is formed, for example, by selectively forming a resist on the first main surface 10a and etching the resist.

As illustrated in FIG. 16A, the second semiconductor region 12 and the third semiconductor region 13 are formed by forming the resist 70 on the first surface and selectively injecting impurities from the surface including the first surface 10c. The second semiconductor region 12 is mainly formed of impurities injected from the first main surface 10a. On the other hand, the third semiconductor region 13 is mainly formed of impurities injected from the first main surface 10a. The second semiconductor region 12 and the third semiconductor region 13 can be formed by the same step.

Then, in FIG. 16B, the resist 70 is formed again on a surface including the first main surface 10a and the first surface 10c, and a portion where the resist 70 is not provided is selectively dug to form the second surface 10d. The second surface 10d is formed by digging the first semiconductor region 11 using a method including, for example, any of RIE, wet etching, or chemical dry etching (CDE).

For example, as illustrated in FIG. 16B, a plurality of second surfaces 10d are formed in the X direction. The plurality of second surfaces 10d can be formed by the same step. In addition, the second surface 10d is in contact with the third semiconductor region 13. The depth of the first surface 10c and the depth of the second surface 10d may be different.

Up to now, the method of manufacturing the semiconductor device 106 according to the sixth embodiment has been described with reference to FIGS. 16A and 16B.

As described above, the embodiments have been described with reference to specific examples. However, the embodiments are not limited to these specific examples. That is, those obtained by appropriately changing the design of these specific examples by those skilled in the art are also included in the scope of the embodiments as long as these have the features of the embodiments. The elements included in each specific example described above and the arrangements, materials, conditions, shapes, sizes, and the like thereof are not limited to those exemplified, and can be appropriately changed.

In addition, the elements included in each of the embodiments described above can be combined as far as technically possible, and combinations thereof are also included in the scope of the embodiments as long as these include the features of the embodiments. In addition, within the scope of the concept of the embodiments, those skilled in the art can conceive various modifications and corrections, and it is understood that those modifications and corrections also fall within the scope of the embodiments.

Although some embodiments of the present invention have been described, these embodiments have been presented as examples, and are not intended to limit the scope of the invention. These novel embodiments can be implemented in various other forms, and various omissions, substitutions, and changes can be made without departing from the gist of the invention. These embodiments or modifications thereof are included in the scope or gist of the invention, and are included in the invention described in the claims and the equivalent scope thereof.

What is claimed is:

1. A semiconductor device having a cell region and a termination region adjacent to the cell region, the semiconductor device comprising:
a semiconductor portion having a first main surface and a second main surface opposite to the first main surface;
a first insulating film provided on the first main surface;
a first electrode provided on the second main surface;
a first semiconductor region of a first conductivity type provided in the semiconductor portion;
a second electrode provided on the first insulating film and electrically connected to the semiconductor portion by a first conductive region;
a gate electrode provided in the semiconductor portion in the cell region;
a gate insulating film covering the gate electrode;
a second semiconductor region of a second conductivity type provided between the first semiconductor region and the first main surface from the cell region to the termination region and in contact with at least a part of a bottom surface of the gate insulating film; and
a first member provided between the second semiconductor region and the first insulating film.

2. The semiconductor device according to claim 1,
wherein, a first surface including an interface between the first member and the second semiconductor region is closer to the first electrode than the first main surface.

3. The semiconductor device according to claim 1,
wherein, the second semiconductor region, the first member, and the second semiconductor region are provided in this order in a termination direction from the cell region to the termination region.

4. The semiconductor device according to claim 1,
wherein the first member is formed of an insulating material.

5. The semiconductor device according to claim 1,
wherein the first member is formed of a conductive material.

6. The semiconductor device according to claim 1,
wherein, in the termination region,
a third electrode provided on the first insulating film, and
a second conductive region located between the third electrode and the second semiconductor region to electrically connect the third electrode and the second semiconductor region to each other
are further provided.

7. The semiconductor device according to claim 6,
wherein, in the termination region,
a third semiconductor region of a second conductivity type provided farther from the cell region than the second semiconductor region and located between the first semiconductor region and the first main surface is further provided.

8. The semiconductor device according to claim 7, further comprising:
a fourth electrode provided on the first insulating film; and
a third conductive region located between the fourth electrode and the third semiconductor region to electrically connect the fourth electrode and the third semiconductor region to each other.

9. The semiconductor device according to claim 8,
wherein the first member is also provided between the third semiconductor region and the first insulating film.

10. The semiconductor device according to claim 9, further comprising:
a fifth electrode provided between the first member and the first insulating film; and
a fourth conductive region located between the fifth electrode and the fourth electrode to electrically connect the fifth electrode and the fourth electrode to each other.

11. The semiconductor device according to claim 1, further comprising:
a gate wiring portion provided on the first member and electrically connected to at least parts of a plurality of the gate electrodes.

12. The semiconductor device according to claim 7,
wherein a first surface including an interface between the first member and the second semiconductor region includes a first bottom portion at least a part of which is parallel to the first main surface and a second bottom portion having a different depth from the first bottom portion,
at least a part of the second semiconductor region is in contact with the first bottom portion, and
at least a part of the third semiconductor region is in contact with the second bottom portion.

13. The semiconductor device according to claim 7,
wherein a second surface including an interface between the first member and the third semiconductor region is spaced apart from a first surface including an interface between the first member and the second semiconductor region, and is formed so as to be divided into a plurality of parts, and
the fifth electrode faces the second surface with the first member interposed therebetween.

14. The semiconductor device according to claim 1,
wherein the semiconductor portion further includes:
a fourth semiconductor region of a second conductivity type provided between the second main surface and the first semiconductor region,
in the cell region,
a fifth semiconductor region of a second conductivity type provided on the first semiconductor region, and
a sixth semiconductor region of a first conductivity type selectively provided on the fifth semiconductor region are further provided,
the gate insulating film is in contact with the fifth semiconductor region and the sixth semiconductor region, and
the first conductive region is in contact with the sixth semiconductor region.

15. A semiconductor device manufacturing method, comprising:
a step of forming a first surface by selectively digging a first main surface of a semiconductor portion;
a step of forming a second semiconductor region of a second conductivity type by injecting impurities into a first semiconductor region of a first conductivity type of the semiconductor portion from the first surface and performing annealing treatment;
a step of forming a first member on the first surface;
a step of forming a gate insulating film, which has a bottom surface at least partially in contact with the second semiconductor region, in the first semiconductor region from the first main surface;
a step of forming a gate electrode covered with the gate insulating film; and
a step of forming a first insulating film on the first main surface.

16. The semiconductor device manufacturing method according to claim 15,
wherein, in the step of forming the second semiconductor region by injecting impurities into the first semiconductor region from the first surface and performing the annealing treatment, a third semiconductor region of a second conductivity type spaced apart from the second semiconductor region is also formed.

17. The semiconductor device manufacturing method according to claim 15 wherein the step of forming the first surface includes a step of forming a first bottom portion at least a part of which is parallel to the first main surface and a second bottom portion having a different depth from the first bottom portion, and
the step of injecting impurities into the semiconductor portion from the first surface includes a step of injecting impurities into the semiconductor portion from the first bottom portion and the second bottom portion.

18. The semiconductor device manufacturing method according to claim 16,
wherein, after the step of forming the third semiconductor region by injecting impurities from the first main surface, a step of forming a second surface at least partially in contact with the third semiconductor region by selectively digging the first main surface, and
a step of forming the first member on the first surface and the second surface
are further included.
